(19) United States
(12) Patent Application Publication
(10) Pub. No.: US 2026/0350496 A1
(43) Pub. Date: Nov. 5, 2026

(54) PRODUCTION MANAGEMENT DEVICE AND PRODUCTION MANAGEMENT METHOD

(71) Applicant: FUJI CORPORATION, Chiryu (JP)

(72) Inventors: Yoshiharu TANIZAWA, Toyota-shi (JP); Kyoya TANAKA, Okazaki-shi (JP)

(73) Assignee: FUJI CORPORATION, Chiryu (JP)

(21) Appl. No.: 19/146,613

(22) PCT Filed: Feb. 22, 2023
(86) PCT No.: PCT/JP2023/006466

§ 371 Date: Jul. 9, 2025

(51) Int. Cl. G06Q 10/0631

(52) U.S. Cl. CPC G06Q 10/06311

(57) ABSTRACT

A production management device includes a transmission section and a handling section. The transmission section is configured to transmit, when a work instruction is issued to a worker of a board work machine configured to perform predetermined board work on a board, a work notification that requires a response to the work instruction to the worker. The handling section is configured to handle work of the worker as necessary based on response content received from the worker.

### TECHNICAL FIELD The present description discloses a technique related to a production management device and a production management method.

### BACKGROUND ART

A facility/terminal intercommunication system described in Patent Literature 1 includes event display means and input means. In the event display means, when information on occurrence of an event on which an operator is to take action is transmitted from a facility, a terminal receives and displays the information. The input means inputs information on a situation as to whether the operator can take action on the event based on the displayed information on the occurrence of the event. Specifically, a portable terminal includes a confirmation button, a transfer button, and a designation button.

The confirmation button is used when the operator can take charge of requested work in response to a message received from a mounting device. The transfer button is used when the operator cannot take charge of (directly take action) the work in response to the message received from the mounting device. The designation button is used when the operator cannot take charge of the work in response to the message received from the mounting device and when the operator wants to designate another operator who takes charge of the work.

### CITATION LIST

### Patent Literature

Patent Literature 1: JP-A-2006-128767

### BRIEF SUMMARY

### Technical Problem

It is not possible for a higher level system to obtain information on a worker's state by only transmitting a work notification to the worker when a work instruction is issued. Therefore, the higher level system cannot handle a case where it is necessary to handle the work of the worker, and there is a possibility that a delay in production of a product board or the like occurs in a production line.

In view of such circumstances, the present description discloses a production management device and a production management method capable of handling work of a worker.

### Solution to Problem

The present description discloses a production management device including a transmission section and a handling section. The transmission section is configured to transmit, when a work instruction is issued to a worker of a board work machine configured to perform predetermined board work on a board, a work notification that requires a response to the work instruction to the worker. The handling section is configured to handle work of the worker as necessary based on response content received from the worker.

The present description discloses a production management method including a transmission step and a handling step. In the transmission step, when a work instruction is issued to a worker of a board work machine configured to perform predetermined board work on a board, a work notification that requires a response to the work instruction is transmitted to the worker, In the handling step, work of the worker is handled as necessary based on response content received from the worker.

### Advantageous Effects

According to the production management device described above, when the work instruction is issued to the worker, the work notification that requires the response to the work instruction can be transmitted to the worker, and the work of the worker can be handled as necessary based on the response content received from the worker. The above description of the production management device can be similarly applied to the production management method.

### BRIEF DESCRIPTION OF DRAWINGS

FIG. 1 is a configuration diagram showing a configuration example of a production line and a production management system.

FIG. 2 is a plan view showing a configuration example of a component mounter.

FIG. 3 is a block diagram showing an example of a control block of a production management device.

FIG. 4 is a flowchart showing an example of a control procedure of the production management device.

FIG. 5 is a schematic diagram showing a display example of options of actions available to a worker.

FIG. 6 is a schematic diagram showing a guidance example of work-related information.

FIG. 7 is a schematic diagram showing an example of a state after the worker selects work.

FIG. 8 is a schematic diagram showing a guidance example of running statuses of the production line and a board work machine,

FIG. 9 is a block diagram showing another example of the control block of the production management device.

FIG. 10 is a flowchart showing another example of the control procedure of the production management device.

FIG. 11 is a schematic diagram showing a display example related to transfer.

### DESCRIPTION OF EMBODIMENTS

### 1. Embodiment

### 1-1. Configuration Example of Production Line WL0

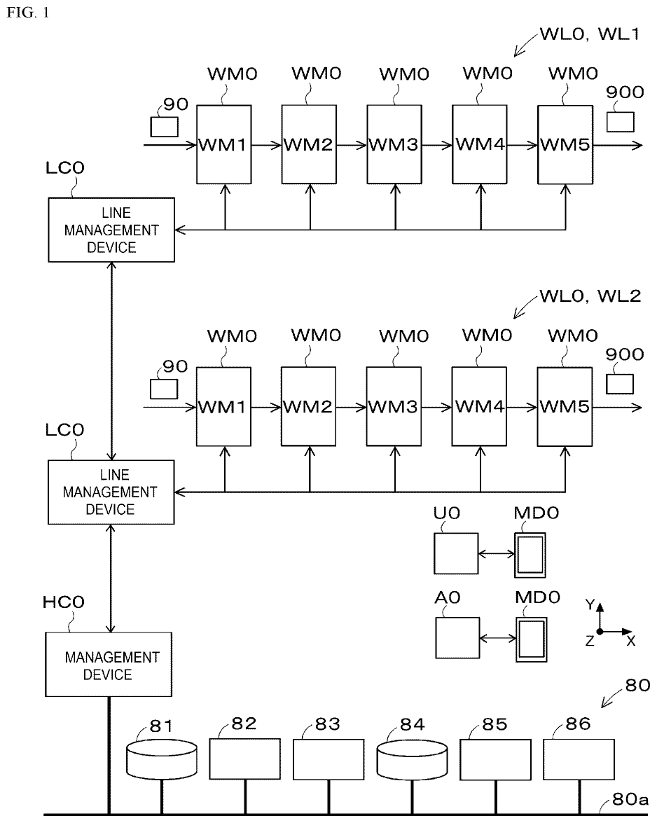

Production management device 50 can be applied to at least one production line WL0 including board work machine WM0. As shown in FIG. 1, a production facility of an embodiment includes two production lines WL0, that is, first production line WL1 and second production line WL2.

In each of two production lines WL0, board work machine WM0 performs predetermined board work on board 90. The type and number of board work machines WM0 constituting production line WL0 are not limited. As shown in FIG. 1, production line WL0 of the embodiment includes multiple board work machines WM0, which are printer WMI, printing inspector WM2, component mounter WM3, reflow oven WM4, and visual inspector WM5, and board 90 is conveyed in order described above by a board conveyance device.

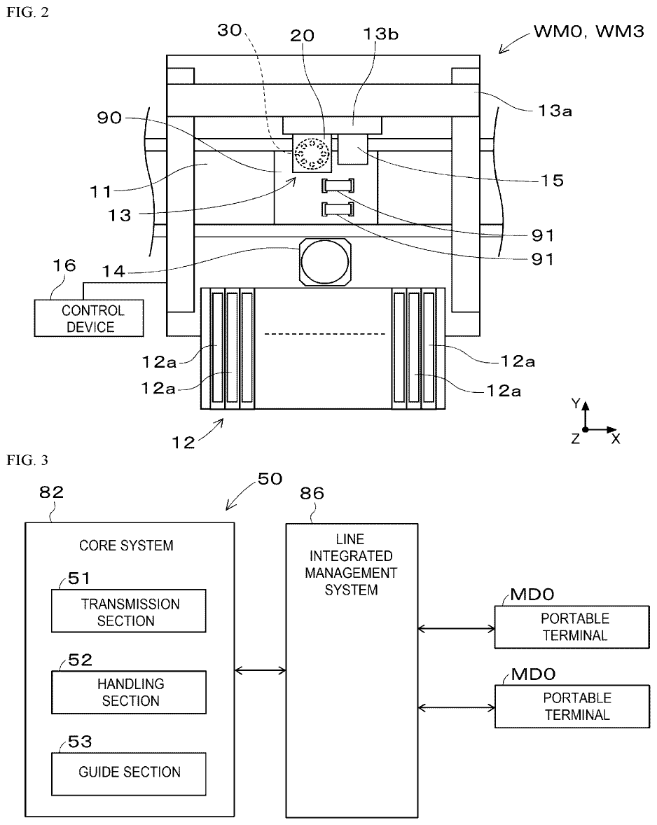

Printer WMI prints solder on mounting positions of multiple components 91 of board 90, Printing inspector WM2 inspects a print state of the solder which is printed by printer WMI. As shown in FIG. 2, component mounter WM3 mounts multiple components 91 on board 90 on which the solder is printed by printer WM1. The number of component mounters WM3 may be one or multiple. When multiple component mounters WM3 are provided, multiple component mounters WM3 can share jobs to mount multiple components 91.

Reflow oven WM4 heats board 90 on which multiple components 91 are mounted by component mounter WM3, causes the solder to melt, and performs soldering. Visual inspector WM5 inspects mounting states or the like of multiple components 91 which are mounted by component mounter WM3. In this way, production line WL0 can convey board 90 in order using multiple board work machines WM0 and execute a production process including an inspection process to thereby produce product board 900. Production line WL0 may include board work machines WM0 such as a function inspector, a buffer device, a board supply device, a board reversing device, a shield mounting device, an adhesive applying device, and an ultraviolet ray irradiation device as necessary.

Multiple board work machines WM0, which constitute production line WL0, and line management device LC0 are connected to be capable of communicating with each other via a communication section. Line management device LC0 and management device HC0 are connected to be capable of communicating with each other via the communication section. The communication section need only be capable of communicably connecting these via wired or wireless communication, and a communication method may take various methods.

In the embodiment, a local area network (LAN) includes multiple board work machines WM0, line management device LC0, and management device HC0. As a result, multiple board work machines WM0 can communicate with one another via the communication section. In addition, multiple board work machines WM0 can communicate with line management device LC0 via the communication section. In addition, line management device LC0 and management device HC0 can communicate with each other via the communication section.

The line management device LC0 controls multiple board work machines WM0 constituting production line WL0 and monitors an operation status of production line WL0. Line management device LC0 stores various types of control data for controlling multiple board work machines WM0. Line management device LC0 transmits control data to each of multiple board work machines WM0. In addition, each of multiple board work machines WM0 transmits its operation status and production status to line management device LC0.

The management device HC0 manages at least one (two in FIG. 1) line management device LC0. For example, the operation status and the production status of board work machine WM0 acquired by line management device LC0 are transmitted to management device HC0 as necessary. Management device HC0 is communicably connected to production management system 80 via wired or wireless communication section 80a. As shown in FIG. 1, production management system 80 includes, for example, maintenance database 81, core system 82, location management system 83, material database 84, layout management system 85, and line integrated management system 86.

Maintenance database 81 stores maintenance information (for example, a maintenance timing, the number of times of maintenance execution, and the like) of an article used in the production of product board 900. Core system 82 is a higher level management system and manages various types of information. Core system 82 can integrally manages, for example, a production plan of product board 900 using board work machine WM0, a progress status of the production of product board 900, and the article used in the production of product board 900. Core system 82 is a well-known integrated management system, and can be provided in a user-side system, for example, Location management system 83 manages location information of the article on a production floor Location management system 83 manages, for example, location information of feeder 12a and a reel described later. Material database 84 stores information on the article. Material database 84 stores, for example, component information, manufacturers of feeder 12a and the reel, and the like. The component information includes information on the number of remaining components and information on electrical characteristics of component 91. The component information is stored in association with identification information of the reel.

Layout management system 85 stores a configuration of production line WL0 for producing product board 900, a configuration of board work machine WM0 provided in each production line WL0, and the like. Line integrated management system 86 performs notification to worker U0, management of remote operation by worker U0, visualization of states of devices including board work machine WM0, and the like in cooperation with the above-described system, and assists in continuing the production of product board 900 in production line WL0.

### 1-2. Configuration Example of Component Mounter WM3

Component mounter WM3 mounts multiple components 91 on board 90. As shown in FIG. 2, component mounter WM3 includes board conveyance device 11, component supply device 12, component transfer device 13, part camera 14, board camera 15, and control device 16.

For example, board conveyance device 11 includes a belt conveyor and the like, and conveys board 90 in a conveyance direction (X-axis direction). Board 90 is a circuit board, on which an electronic circuit, an electric circuit, a magnetic circuit, and the like are formed. Board conveyance device 11 carries board 90 into component mounter WM3, and positions board 90 at a predetermined position inside component mounter WM3. After a mounting process of multiple components 91 using component mounter WM3 is ended, board conveyance device 11 carries board 90 out of component mounter WM3.

Component supply device 12 supplies multiple components 91 to be mounted on board 90. Component supply device 12 includes multiple feeders 12a, which are provided along the conveyance direction (X-axis direction) of board 90. Each of multiple feeders 12a is equipped with the reel. A carrier tape accommodating multiple components 91 is wound around the reel. Feeder 12a feeds the carrier tape pitch by pitch to supply components 91 such that component 91 can be picked up at a supply position located on a distal end side of feeder 12a. In addition, component supply device 12 can also supply an electronic component (for example, a lead component or the like) which is relatively large as compared with a chip component or the like in a state of being disposed on a tray.

Component transfer device 13 includes head driving device 13a and moving table 13b, Head driving device 13a is configured to move moving table 13b in the X-axis direction and a Y-axis direction (a direction orthogonal to the X-axis direction on a horizontal plane) by means of a linear motion mechanism. Mounting head 20 is detachably (exchangeably) provided on moving table 13b by a clamp member. Mounting head 20 picks up and holds component 91 supplied by component supply device 12 by using at least one holding member 30, and mounts component 91 on board 90 positioned by board conveyance device 11. For example, a suction nozzle, a chuck, or the like can be used as holding member 30.

As part camera 14 and board camera 15, a well-known imaging device can be used. Part camera 14 is fixed to a base of component mounter WM3 such that an optical axis thereof is oriented upwards in a vertical direction (a Z-axis direction orthogonal to the X-axis direction and the Y-axis direction). Part camera 14 can image component 91 held by holding member 30 from below. Board camera 15 is provided on moving table 13b of component transfer device 13 such that an optical axis thereof is oriented downwards in the vertical direction (the Z-axis direction). Board camera 15 can image board 90 from above, Part camera 14 and board camera 15 perform imaging based on a control signal transmitted from control device 16, Image data of the image captured by part camera 14 and board camera 15 is transmitted to control device 16.

Control device 16 includes a computing device and a storage device which are well-known, and is provided with a control circuit. The information, image data, and the like output from various sensors provided in component mounter WM3 are input to control device 16. Control device 16 transmits control signals to each device based on a control program, a predetermined mounting condition set in advance, and the like.

For example, control device 16 causes board camera 15 to image board 90 positioned by board conveyance device 11. Control device 16 performs image processing on the image captured by board camera 15 to recognize a positioning state of board 90. Moreover, control device 16 causes holding member 30 to pick up and hold component 91 supplied by component supply device 12, and causes part camera 14 to image component 91 held by holding member 30. Control device 16 performs the image processing on the image captured by part camera 14 to recognize a holding posture of component 91.

Control device 16 moves holding member 30 toward above a planned mounting position that is set in advance by the control program or the like. Further, based on the positioning state of board 90, the holding posture of component 91, and the like, control device 16 corrects the planned mounting position to set the mounting position on which component 91 is actually mounted. The planned mounting position and the mounting position include a rotation angle in addition to the position (X-axis coordinate and Y-axis coordinate).

Control device 16 corrects a target position (the X-axis coordinate and the Y-axis coordinate) and the rotation angle of holding member 30 according to the mounting position. Control device 16 lowers holding member 30 at the corrected rotation angle at the corrected target position to mount component 91 on board 90. Control device 16 repeats the pick-and-place cycle described above to execute the mounting process of mounting multiple components 91 on board 90. A total time of a time required for a predetermined number of cycles of the pick-and-place cycle described above and a time required for the carrying-in and carrying-out of board 90 corresponds to a cycle time per board

### 1-3. Configuration Example of Production Management Device 50

For example, in component mounter WM3, changeover work is performed when the type of product board 900 to be produced is switched. In addition, in component mounter WM3, when component 91 that can be supplied from component supply device 12 is insufficient, replenishment work of component 91 is performed. The changeover work and the replenishment work are performed by, for example, worker U0, and feeder 12a and the like are exchanged. The above description of component mounter WM3 can be similarly applied to other board work machines WM0. For example, in printer WM1, a mask or the like is exchanged by worker U0.

In this way, when causing worker U0 to perform work, the higher level system transmits a work notification to worker U0. However, it is not possible for the higher level system to obtain information on worker U0's state by only transmitting the work notification to worker U0. Therefore, the higher level system cannot handle a case where it is necessary to handle the work of worker U0, and there is a possibility that a delay in the production of product board 900 or the like occurs in production line WL0.

The production facility of the embodiment is provided with production management device 50. When viewed as a control block, production management device 50 includes transmission section 51 and handling section 52. Production management device 50 can also include guide section 53. Transmission section 51, handling section 52, and guide section 53 can be provided in various control devices. For example, at least one of transmission section 51, handling section 52, and guide section 53 can be provided in line integrated management system 86.

At least one of transmission section 51, handling section 52, and guide section 53 may be provided in core system 82 or the like, At least one of transmission section 51, handling section 52, and guide section 53 may be formed on a cloud. As shown in FIG. 3, in production management device 50 of the embodiment, transmission section 51, handling section 52, and guide section 53 are provided in core system 82. Worker U0 is notified of the work notification from core system 82 via line integrated management system 86 and portable terminal MD0. Portable terminal MD0 need only be a communication device that can be carried by worker U0, and is not limited.

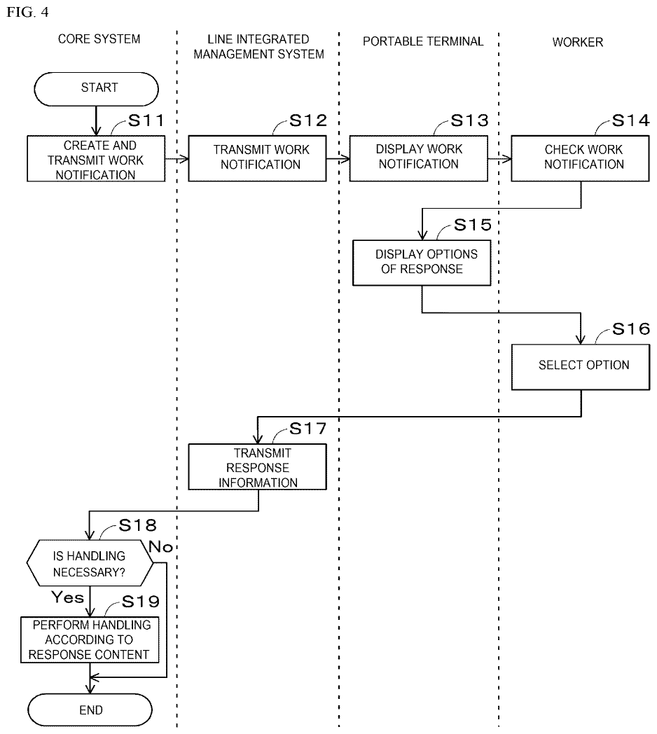

Production management device 50 of the embodiment executes control according to a flowchart shown in FIG. 4. In the drawing, the processes and determinations performed by core system 82, line integrated management system 86, portable terminal MD0, and worker U0 are divided by dashed straight lines. In the present description, transmission section 51, handling section 52, and guide section 53 are described with reference to the flowchart shown in FIG. 4. The matters described in the present description can be appropriately selected and applied. Further, the matters described in the present description can be appropriately combined.

### 1-3-1. Transmission Section 51 and Handling Section 52

When the work instruction is issued to worker U0 of board work machine WM0, transmission section 51 transmits, to worker U0, the work notification that requires a response to the work instruction. The work notification need only notify worker U0 of the work instruction and request the response of worker U0 to the work instruction, and may take various forms. For example, transmission section 51 can transmit the work notification to worker U0 through the network shown in FIG. 1.

Specifically, as shown in FIG. 4, transmission section S1 creates the work notification and transmits the work notification to line integrated management system 86 (step S11). For example, the work notification includes information on production line WL0 and board work machine WM0 on which worker U0 performs the work (including a module number or the like with which it is possible to identify board work machines WM0 when production line WL0 includes multiple board work machines WM0 of the same type), and the like. In addition, the work notification includes information on a work completion time by which worker U0 is to complete the work, work content, and the like. The work notification can be transmitted ahead of the work completion time by a time obtained by adding a required time when worker U0 performs the work and a predetermined margin time. The work notification can also be transmitted at a desired timing.

Line integrated management system 86 transmits the work notification to portable terminal MD0 of worker U0 who is to perform the work (step S12), Then, portable terminal MD0 displays the work notification (step S13), Worker U0 checks the work notification (step S14) and responds to the work instruction. A form of the response is not limited, and various forms can be adopted. For example, worker U0 can respond by text input, handwriting input, voice input, or the like using portable terminal MD0. However, in these cases, there is a possibility that response work of worker U0 is complicated. Further, in these cases, there is a possibility that a process on a side of receiving the response is complicated.

Therefore, it is preferable that transmission section 51 transmits the work notification in which an action available to worker U0 in response to the work instruction is selectable from among multiple options. The types and the number of the multiple options are not limited, and may include various actions available to worker U0. For example, the multiple options may be at least two of an acceptance action, a rejection action, a delay action, a work-unnecessary action, a shift-change action, and a clarification-needed action.

The acceptance action refers to an action in which worker U0 performs the work. The rejection action refers to an action in which worker U0 does not perform the work. The delay action refers to an action in which it takes time for worker U0 to start the work. The work-unnecessary action refers to an action in which worker U0 determines that the work is unnecessary. The shift-change action refers to an action in which the work is reassigned to other worker U0. The clarification-needed action refers to an action indicating that content of the work instruction is unclear.

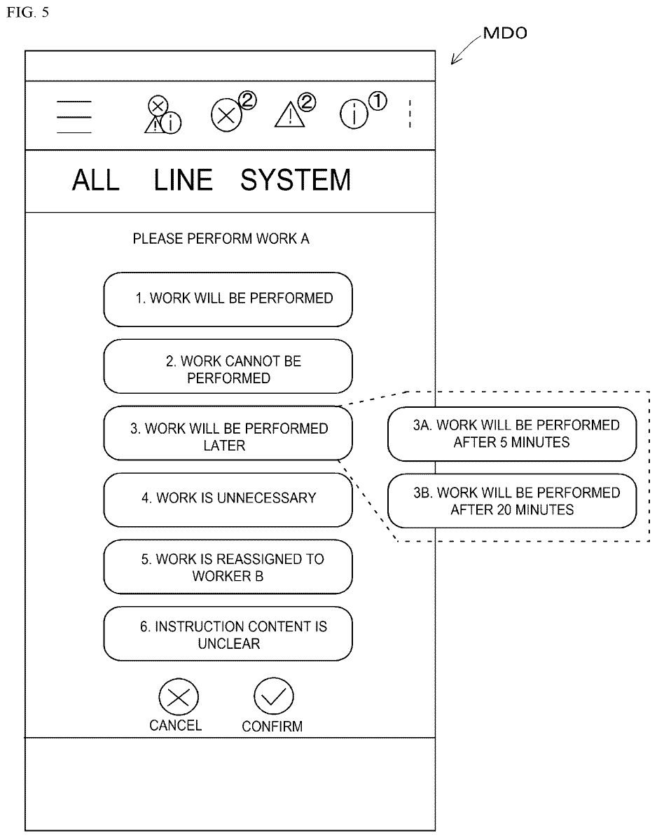

FIG. 5 is an example of a display screen of portable terminal MD0, and shows a display example of options of actions available to a worker. In the example shown in the drawing, the acceptance action corresponds to “1. Work will be performed”. The rejection action corresponds to “2. Work cannot be performed”. The delay action corresponds to “3. Work will be performed later”. The work-unnecessary action corresponds to “4. Work is unnecessary”. The shift-change action corresponds to “5. Work is reassigned to worker B”. The clarification-needed action corresponds to “6. Instruction content is unclear”.

In this way, portable terminal MD0 displays the options of the response (step S15). Then, worker U0 selects one option from among the multiple options (step S16). In the example shown in FIG. 5, worker U0 selects (taps) one option from among six options of No. 1 to No. 6 and presses (taps) a confirmation button. As a result, the response is made to the work notification.

Response information transmitted from portable terminal MD0 is transmitted to line integrated management system 86. Then, the response information is transmitted from line integrated management system 86 to core system 82 (step S17), When worker U0 presses (taps) a cancel button on the display screen shown in FIG. 5, the screen returns from a selection screen of the response to a normal screen.

Handling section 52 handles the work of worker U0 as necessary based on the response content received from worker UD. Handling section 52 need only handle the work of worker U0 as necessary, and may take various forms. For example, when worker U0 responses through handwriting input using portable terminal MD0, handling section 52 can convert response data into text by, for example, an optical character recognition device.

When worker U0 responses through voice input using portable terminal MD0, handling section 52 can perform voice recognition and convert response data into text. Handling section 52 learns the response data returned through text input and the response data converted into text via, for example, machine learning or the like, and can recognize the response content received from worker U0.

In addition, transmission section 51 of the embodiment transmits the work notification in which an action available to worker U0 in response to the work instruction is selectable from among the multiple options. In this case, handling section 52 can handle the action selected by worker U0 as necessary. Specifically, handling section 52 determines whether handling is necessary for the action selected by worker U0 (step S18). When the handling is necessary (Yes in step S18), handling section 52 performs handling according to the response content (step S19). Then, the control is temporarily ended. When the handling is unnecessary (No in step S18), the control temporarily is ended without performing the process shown in step S19.

For example, on the display screen shown in FIG. 5, when worker U0 selects the acceptance action (corresponding to “1. Work will be performed”), handling section 52 does not need to handle the action. Meanwhile, when worker U0 selects another action, handling section 52 needs to handle the action selected by worker U0. Specifically, when the response content received from worker U0 is the shift-change action, handling section 52 causes transmission section 51 to transmit the work notification to other worker U0 to whom the work is reassigned.

Accordingly, the work notification is transmitted to other worker U0 to whom the work is reassigned. Worker U0 to whom the work is reassigned responses to the work notification by the same method as the above-described method. Worker U0 to whom the work is reassigned performs a response in which the acceptance action (corresponding to “1. Work will be performed”) is selected, so that the work of which notification is given to initial worker U0 is reassigned. Transmission section 51 of the embodiment is provided in core system 82. Core system 82 integrally manages the production plan of product board 900 using board work machine WM0, the progress status of the production of product board 900, and the articles used in the production of product board 900. Core system 82 can also manage the work of worker U0.

In this case, transmission section 51 can easily obtain information on a work status of worker U0, and can select worker U0 to whom the work is reassigned based on the work status of worker U0. In the embodiment, worker U0 to whom the work is reassigned is designated by transmission section 51 in the options of actions available to worker U0. In the example shown in FIG. 5, worker B is designated. Meanwhile, worker U0 who has received the work notification can also designate other worker U0 to whom the work is reassigned.

For example, transmission section 51 can transmit a work notification in which worker U0 can select worker U0 to whom the work is reassigned, in the option of the shift-change action. In this case, the response includes information on worker U0 to whom the work is reassigned. Accordingly, handling section 52 can recognize worker U0 to whom the work is reassigned. When there is no problem in that worker U0 designated by worker U0 performs the work, handling section 52 can also approve the reassignment of the work. When there is a problem in that worker U0 designated by worker U0 performs the work, handling section 52 can also cancel the reassignment of the work.

Further, transmission section 51 can give the work notification to appropriate worker U0 at an appropriate timing based on the work status of worker U0. Therefore, the rejection action, the delay action, the work-unnecessary action, and the clarification-needed action are not preferable as an action available to worker U0. Therefore, in a case where the response content received from worker U0 is the rejection action, the delay action, the work-unnecessary action, or the clarification-needed action, handling section 52 can request administrator AO to provide guidance to worker U0.

As a result, worker U0 can receive necessary guidance from administrator A0 at a timing when guidance is necessary. Administrator A0 need only be a person who provides guidance to and manages worker U0, and is not limited. For example, an engineer, a team leader, and the like are included in administrator A0. A guidance request for worker U0 can be performed by various methods. Handling section 52 can make the guidance request for worker U0 to administrator A0 by using, for example, portable terminal MD0 carried by administrator A0.

In addition, in a case where the response content received from worker U0 is the rejection action, the delay action, or the shift-change action, there is a possibility that worker U0's work plan is changed. Therefore, handling section 52 can adjust worker U0's work plan in a case where the response content received from worker U0 is the rejection action, the delay action, or the shift-change action.

For example, in a case where the response content received from worker U0 is the rejection action or the shift-change action, handling section 52 assigns the work of worker U0 to other worker U0. In this case, handling section 52 causes transmission section 51 to transmit the work notification to other worker U0 to whom the work is assigned. When the response content received from worker U0 is the delay action, handling section 52 adjusts worker U0's work plan according to a degree of delay. For example, when a time required for worker U0 to start the work is within an allowable range, handling section 52 changes the work completion time by which the work is to be completed in accordance with the required time.

When the time required to start the work exceeds the allowable range, handling section 52 can also assign the work of worker U0 to other worker U0. In this case, handling section 52 causes transmission section 51 to transmit the work notification to other worker U0 to whom the work is assigned. In this way, handling section 52 can adjust worker U0's work plan. Handling section 52 can also adjust worker U0's work plan when the response content received from worker U0 is the work-unnecessary action or the clarification-needed action. Further, handling section 52 can also adjust the production plan of product board 900.

In addition, in a case where the response content received from worker U0 is the delay action, worker U0 is more likely to forget to work as compared with the acceptance action by the delay in the start of the work. Therefore, it is preferable that handling section 52 alerts worker U0. Specifically, when the response content received from worker U0 is the delay action, handling section 52 causes transmission section 51 to retransmit the work notification at a timing when a predetermined time has elapsed from the reception of the delay action. As a result, worker 00 is less likely to forget to work.

The predetermined time (a timing of retransmission of the work notification) can be set as desired. For example, handling section 52 acquires the relationship between the elapsed time from the reception of the delay action and a frequency of work forgetting via verification performed by worker U0. Then, handling section 52 can set the elapsed time in which the frequency of work forgetting exceeds the allowable range as the predetermined time (the timing of retransmission of the work notification).

Transmission section SI can also transmit a work notification in which a time until worker U0 starts the work can be selected, in the option of the delay action. In this case, the response includes information on the time until worker U0 starts the work. Accordingly, handling section 52 can recognize the time until worker U0 starts the work. Therefore, when the response content received from worker U0 is the delay action, handling section 52 can cause transmission section 51 to retransmit the work notification at the timing when the time selected by worker U0 until the work is started has elapsed from the reception of the delay action.

On the display screen shown in FIG. 5, worker U can also select “3A. Work will be performed after 5 minutes” or “3B. Work will be performed after 20 minutes” as the delay action. For example, when worker U0 selects the former, handling section 52 causes transmission section 51 to retransmit the work notification at a timing when five minutes have elapsed from the reception of the delay action. When worker U0 selects the latter, handling section 52 causes transmission section 51 to retransmit the work notification at a timing when 20 minutes have elapsed from the reception of the delay action. Accordingly, worker U0 can recognize the work at a timing when the work is to be started, and worker U0 is less likely to forget to work. The retransmission of the work notification can be repeated until worker U0 performs the response of the acceptance action.

Even when the response content received from worker U0 is other than the delay action, handling section 52 can request worker U0 to response again regarding the response content received from worker U0. For example, when the response content received from worker U0 is the clarification-needed action, handling section 52 can ask worker U0, for example, whether a work method related to the work instruction is unclear or a location of a member necessary for the work is unclear. In addition, handling section 52 can also provide an instruction on a solution to an assumed unclear point. As a result, it is expected that worker U0 performs the response of the acceptance action, and for example, a burden on administrator A0 is reduced. In addition, worker U0 can ask handling section 52 an unclear point or the like regardless of the presence or absence of the work notification.

### 1-3-2. Guide Section 53

Guide section 53 provides work-related information to worker U0. Guide section 53 need only be capable of providing the work-related information, and may take various forms. Guide section 53 of the embodiment provides the work-related information to portable terminal MD0 carried by worker U0. In addition, guide section 53 provides the work-related information to worker U0 in order from the work in which a degree of priority of the work performed by worker U0 is high and a time remaining before the work completion time by which the work is to be completed is short. As a result, worker U0 can obtain the necessary work-related information in the order from the work to be performed. In addition, worker U0 can perform the above-described response while referring to the work-related information in the order from the work to be performed.

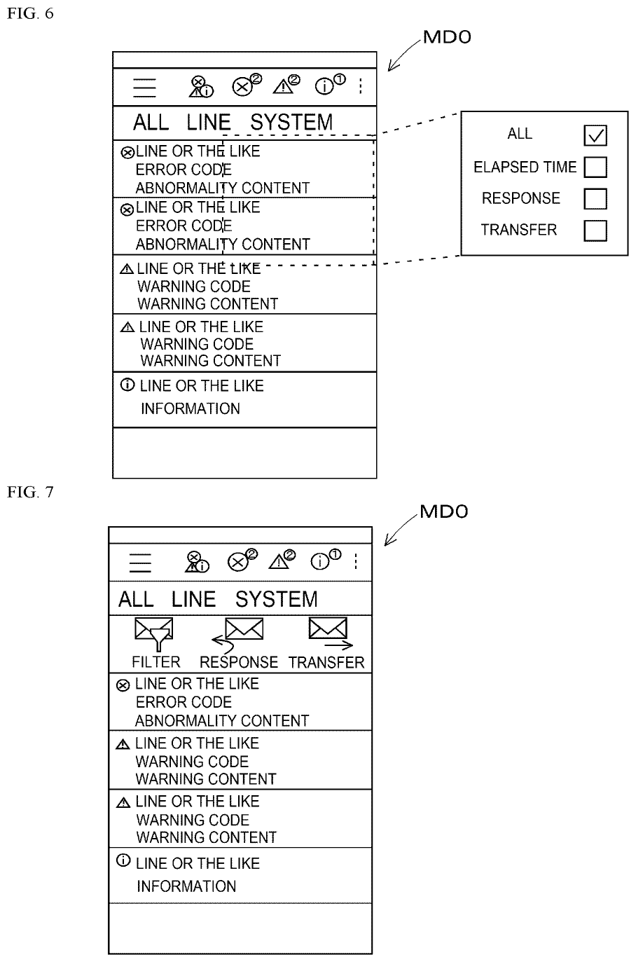

FIG. 6 is a display screen different from the display screen of FIG. 5, and shows a guidance example of the work-related information. In the drawing, the work is classified into three categories of abnormality, warning, and information in descending order of a degree of priority of the work performed by worker U0. The work classified into the abnormality is, for example, work of handling a case where an abnormality occurs in board work machine WM0, and is indicated, in the drawing, by an icon in which a cross is attached to a circle. The work classified into the warning is, for example, work of handling a case where a problem occurs in a changeover area, and is indicated, in the drawing, by an icon in which an exclamation mark is attached to a triangle.

The work classified into the information is, for example, work of handling a case where a problem occurs in a warehouse area, and is indicated by, in the drawing, an icon in which the Roman alphabet “i” (corresponding to an initial character in a case where “information” is written in English) is attached to a circle. A number surrounded by a circle in the vicinity of each icon indicates the number of times of work of the corresponding work. The more the work is classified into the abnormality, the shorter the time remaining before the work completion time by which the work is to be completed, and the more urgent it is. The time remaining before the work completion time increases in the order the work classified into the abnormality, the work classified into the warning, and the work classified into the information.

In the display screen shown in FIG. 6, two pieces of work classified into the abnormality are displayed in an upper part of the display screen. In addition, two pieces of work classified into the warning are displayed in a middle part of the display screen. Further, one piece of work classified into the information is displayed in a lower part of the display screen. The work-related information need only be information related to the work of worker U0, and is not limited. For example, the work-related information includes the line or the like, an error code, abnormality content, a warning code, warning content, and the information shown in the drawing.

The line or the like indicates information with which it is possible to identify production line WL0 provided with board work machine WM0 and board work machine WM0. The error code indicates information with which it is possible to identify a type of the abnormality The abnormality content indicates the content of the abnormality. The warning code indicates information with which it is possible to identify a type of warning. The warning content indicates the content of the warning. The information indicates the content of the work classified into the information. When worker U0 presses (taps) specific work, guide section 53 can display more detailed work-related information for the work. For example, guide section 53 can display work-related information such as a cause of the abnormality, a countermeasure against the abnormality, a link (Internet address) in which a countermeasure method is described, a work process, an action time, and a number identifying a slot in which target feeder 12a is mounted.

Guide section 53 can also change the work-related information to be provided in response to a request from worker U0. In the example shown in FIG. 6, worker U0 presses (taps) an icon at the top of the display screen shown in the drawing, so that guide section 53 can change the display to guidance of all the work, guidance of only the work classified into the abnormality, guidance of only the work classified into the warning, or guidance of only the work classified into the information. In addition, worker U0 selects (taps) an option displayed in a rectangular region indicated by a broken line in the drawing, so that guide section 53 can also change the display to guidance of all the work, guidance according to the elapsed time, guidance according to the presence or absence of the response, or guidance according to the presence or absence of transfer. In the present description, a form in which worker U0 who has received the work notification designates worker U0 to whom the work is reassigned is referred to as the transfer.

As shown in FIG. 7, when worker U0 operates (swipes) specific work, guide section 53 can also change the display screen to a display screen related to a filter, the response, or the transfer. On the display screen of the filter, as described above, worker U0 can change the work-related information to be provided, The display screen of the response is similar to the display screen shown in FIG. 5, and worker U0 can response to the work notification. On the transfer display screen, worker U0 can designate worker U0 to whom the work is reassigned.

Worker U0 can also select (tap) all, a line, or a system on the display screens shown in FIGS. 5 to 7. According to the selection of worker U0, guide section 53 can change the display to guidance of the work-related information on all production lines WL0 and board work machine WM0, guidance of only the work-related information on specific production line WL0 and specific board work machine WM0, or guidance of only the work-related information on a specific control system.

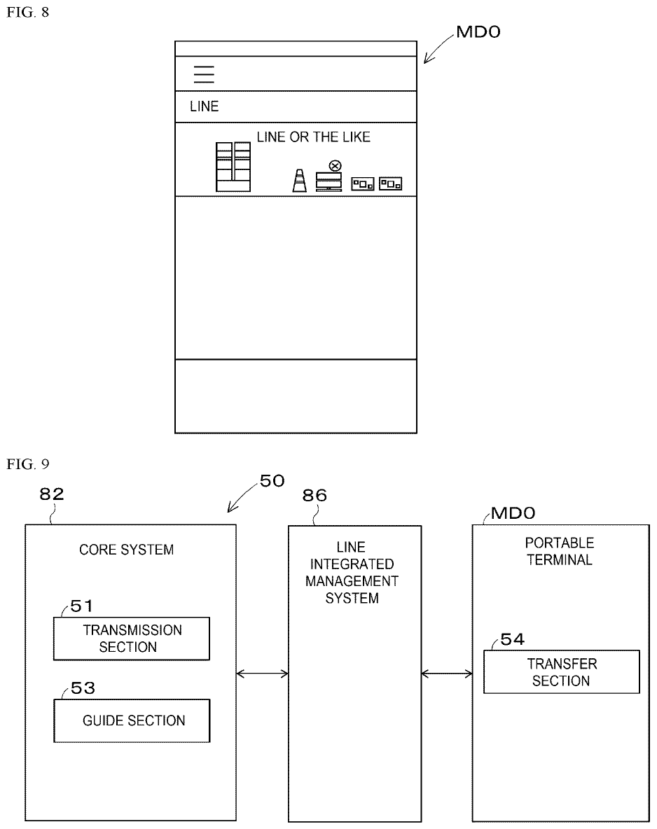

The work-related information includes a running status of at least one of production line WL0 provided with board work machine WM0 and board work machine WM0. For example, when worker U0 selects (taps) an icon for visualizing the states of the devices on the display screen displaying the detailed work-related information described above, a screen shown in FIG. 8 is displayed. In the display screen shown in the drawing, guide section 53 provides information on running statuses of production line WL0 provided with board work machine WM0 and board work machine WM0.

For example, guide section 53 can provide the information on the line or the like (information with which it is possible to identify production line WL0, information with which it is possible to identify board work machine WM0, or the like). In addition, guide section 53 can also provide information on board work machine WM0 that is a bottleneck, by using, for example, an icon simulating a conical figurine having a white line on a red main body section used at a construction site. Board work machine WM0 that is a bottleneck is board work machine WM0 having a longest cycle time. Further, guide section 53 can provide information on a connection state (for example, the presence or absence of activation) of board work machine WM0 by using an icon simulating board work machine WM0. Guide section 53 can also provide information on a state of board 90 (for example, the number of boards 90) carried into board work machine WM0.

### 1-3-3. Other Forms

For example, when worker U0 cannot take action for the work instruction, there is a possibility that the production of product board 900 is stopped in production line WL0. Therefore, as shown in FIG. 9, production management device 50 may include transmission section 51 and transfer section 54. Production management device 50 may also include guide section 53. Production management device 50 shown in the drawing includes transmission section 51, guide section 53, and transfer section 54. Transmission section 51, guide section 53, and transfer section 54 may be provided in various control devices, communication devices, and the like, and may also be formed on a cloud.

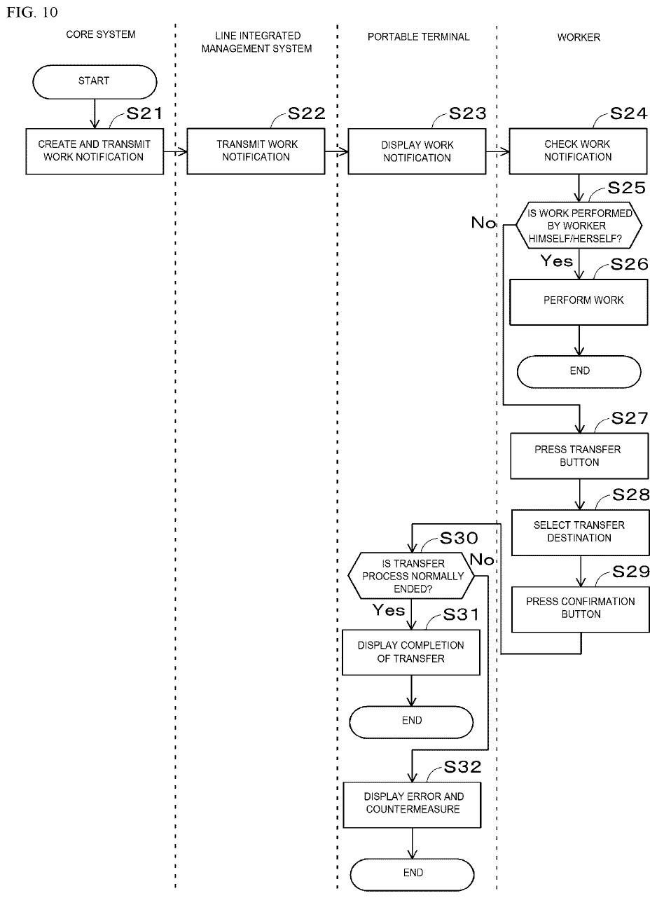

As shown in FIG. 9, for example, transmission section 51 and guide section 53 are provided in core system 82, and transfer section 54 is provided in portable terminal MD0. Production management device 50 shown in FIG. 9 executes control according to a flowchart shown in FIG. 10. In the drawing, the processes and determinations performed by core system 82, line integrated management system 86, portable terminal MD0, and worker U0 are divided by dashed straight lines.

Transmission section 51 transmits the work notification to worker DO when the work instruction is issued to worker U0 of board work machine WM0. In the forms shown in FIGS. 9 and 10, the work notification does not require the response to the work instruction. Transmission section 51 creates the work notification and transmits the work notification to line integrated management system 86 (step S21). The work notification may include information similar to the above-described work notification.

Line integrated management system 86 transmits the work notification to portable terminal MD0 of worker U0 who is caused to perform the work (step S22). Then, portable terminal MD0 displays the work notification (step S23). Worker U0 checks the work notification (step S24), and determines whether to perform the work by himself/herself (step S25), When worker U0 performs the work by himself/herself (Yes in step S25), worker U0 performs the work (step S26). Then, the control is temporarily ended.

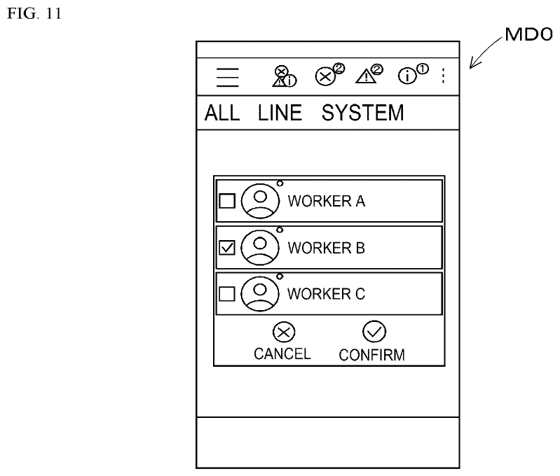

When worker U0 does not perform the work by himself/herself (No in step S25), worker U0 presses (taps) a transfer button on the display screen of portable terminal MD0 (step S27). Then, worker U0 selects a transfer destination on the display screen of portable terminal MD0 (step S28). As described above, the transfer refers to the form in which worker U0 who has received the work notification designates worker U0 to whom the work is reassigned. FIG. 11 is an example of the display screen of portable terminal MD0, and shows a display example related to the transfer.

Worker U0 selects (taps) worker U0 to whom the work is reassigned from among three workers U0 of worker A to worker C on the display screen shown in FIG. 11, and presses (taps) the confirmation button (step S29). Accordingly, worker U0 to whom the work is reassigned is designated, and the work notification is transmitted to designated worker U0. When worker U0 presses (taps) a cancel button on the display screen shown in FIG. 11, the screen returns from a selection screen of the transfer destination to a normal screen.

Portable terminal MD0 determines whether a transfer process is normally ended (step S30). When the transfer process is normally completed (Yes in step S30), portable terminal MD0 displays the completion of the transfer process (step S31). Then, the control is temporarily ended. When the transfer process is not normally ended (No in step S30), portable terminal MD0 performs display (error display) indicating that the transfer process is not normally ended and countermeasure display such as retransmission (step S32). Then, the control is temporarily ended.

As described above, in the forms shown in FIGS. 9 and 10, when worker U0 cannot take action for the work instruction, worker U0 to whom the work is reassigned is designated, so that the possibility that the production of product board 900 is stopped in production line WL0 is reduced. Also in the forms shown in FIGS. 9 and 10, the above-described matters (for example, the display screen) can be appropriately applied.

### 2. Production Management Method

The above description of production management device 50 can be similarly applied to a production management method Specifically, the production management method includes a transmission step and a handling step. The transmission step corresponds to control performed by transmission section 51. The handling step corresponds to control performed by handling section 52. The production management method may include a guidance step. The guidance step corresponds to control performed by guide section 53.

As described in the other forms, the production management method may include the transmission step and a transfer step. The transmission step corresponds to control performed by transmission section 51. The transfer step corresponds to control performed by transfer section 54. The production management method may include a guidance step. The guidance step corresponds to control performed by guide section 53.

### 3. Example of Effects of Embodiment

With production management device 50, when the work instruction is issued to worker U0, the work notification that requires the response to the work instruction can be transmitted to worker U0, and the work of worker U0 can be handled as necessary based on the response content received from worker U0. The above description of production management device 50 can be similarly applied to the production management method.

### REFERENCE SIGNS LIST

50; production management device, 51: transmission section, 52: handling section, 53: guide section,
82; core system, 90; board, 900; product board, U0: worker, A0: administrator, WL0: production line, WM0: board work machine.

1. A production management device comprising:
a transmission section configured to transmit, when a work instruction is issued to a worker of a board work machine configured to perform predetermined board work on a board, a work notification that requires a response to the work instruction to the worker; and
a handling section configured to handle work of the worker as necessary based on response content received from the worker.

2. The production management device according to claim 1,
wherein the transmission section is configured to transmit the work notification in which an action available to the worker in response to the work instruction is selectable from among multiple options, and
the handling section is configured to handle the action selected by the worker as necessary.

3. The production management device according to claim 2,
wherein the multiple options include at least two of an acceptance action in which the worker performs the work, a rejection action in which the worker does not perform the work, a delay action in which it takes time for the worker to start the work, a work-unnecessary action in which the worker determines that the work is unnecessary, a shift-change action in which the work is reassigned to another worker, and a clarification-needed action indicating that content of the work instruction is unclear.

4. The production management device according to claim 3, wherein the handling section is configured to cause, when the response content received from the worker is the shift-change action, the transmission section to transmit the work notification to the other worker to whom the work is reassigned.

5. The production management device according to claim 3, wherein the handling section is configured to request, when the response content received from the worker is the rejection action, the delay action, the work-unnecessary action, or the clarification-needed action, an administrator to provide guidance to the worker.

6. The production management device according to claim 3, wherein the handling section is configured to adjust, when the response content received from the worker is the rejection action, the delay action, or the shift-change action, a work plan of the worker.

7. The production management device according to claim 3, wherein the handling section is configured to cause, when the response content received from the worker is the delay action, the transmission section to retransmit the work notification at a timing when a predetermined time has elapsed from reception of the delay action.

8. The production management device according to claim 1, further comprising:
a guide section configured to provide work-related information to the worker in order from the work in which a degree of priority of the work performed by the worker is high and a time remaining before a work completion time by which the work is to be completed is short.

9. The production management device according to claim 8, wherein the guide section is configured to change, in response to a request from the worker, the work-related information to be provided.

10. The production management device according to claim 8, wherein the work-related information includes a running status of at least one of a production line provided with the board work machine and the board work machine.

11. The production management device according to claim 1, wherein the transmission section is provided in a core system that integrally manages a production plan of a product board using the board work machine, a progress status of production of the product board, and an article used in the production of the product board.

12. A production management method comprising:
a transmission step of transmitting, when a work instruction is issued to a worker of a board work machine configured to perform predetermined board work on a board, a work notification that requires a response to the work instruction to the worker; and
a handling step of handling work of the worker as necessary based on response content received from the worker.
